(19) United States
(12) Patent Application Publication
(10) Pub. No.: US 2026/0353777 A1
(43) Pub. Date: Nov. 5, 2026

(54) BACKSIDE GATE CONTACT AND METHODS OF FORMING THE SAME

(71) Applicant: Taiwan Semiconductor Manufacturing Co., Ltd., Hsinchu (TW)

(72) Inventors: Yi-Hsuan Li, Hsinchu (TW); Wei-De Ho, Hsinchu (TW); Ching Yen Lee, Hsinchu (TW); Szuya Liao, Zhubei (TW)

(21) Appl. No.: 19/739,474

(22) Filed: Jul. 13, 2026

Related U.S. Application Data
(63) Continuation of application No. 19/040,137, filed on Jan. 29, 2025.
(60) Provisional application No. 63/694,246, filed on Sep. 13, 2024.

(51) Int. Cl. H10D 84/83; H10D 84/01; H10D 84/85; H10P 14/60; H10D 64/01

(52) U.S. Cl. CPC H10D 84/83138; H10D 84/0179; H10D 84/0184; H10D 84/0188; H10D 84/8316; H10D 84/851; H10D 84/856; H10P 14/6336; H10D 64/017; H10D 84/017

(57) ABSTRACT

In an embodiment, a method includes forming a multi-layer stack over a semiconductor substrate, patterning the multi-layer stack and the semiconductor substrate to form a fin structure, the fin structure including alternating semiconductor nanostructures and dummy nanostructures, where a bottommost dummy nanostructure of the dummy nanostructures has a first thickness, where first dummy nanostructures of the dummy nanostructures are disposed above the bottommost dummy nanostructure, and each of the first dummy nanostructures has a second thickness that is smaller than the first thickness, forming source/drain recesses in the fin structure, etching sidewalls of the first dummy nanostructures and the bottommost dummy nanostructure in the source/drain recesses to form sidewall recesses, forming inner spacers in the sidewall recesses in the first dummy nanostructures and the bottommost dummy nanostructure, and replacing the first dummy nanostructures and the bottommost dummy nanostructure with a gate structure.

### CROSS-REFERENCE TO RELATED APPLICATIONS

This application is a continuation of U.S. Patent Application No. 19/040,137 filed on Jan. 29, 2025, which application claims priority to U.S. Application No. 63/694,246, filed on Sep. 13, 2024, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic of a stacked transistor, such as a complementary field-effect transistor (CFET), in a three-dimensional view, in accordance with some embodiments.

FIGS. 2-13B are views of intermediate stages in the manufacturing of CFETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a semiconductor device may be formed that includes CFETs. A CFET includes a lower nanostructure-FET and an upper nanostructure-FET. Forming the semiconductor device may comprise forming a fin structure that includes alternating dummy nanostructures and semiconductor nanostructures that are disposed over a fin. The semiconductor nanostructures may subsequently form channel regions for the CFETs. A bottommost dummy nanostructure of the dummy nanostructures may have a thickness that is greater than thicknesses of the other dummy nanostructures. Sidewalls of first ones of the dummy nanostructures (e.g., including the bottommost dummy nanostructure) may be recessed to form sidewall recesses. Spacers may be formed in the sidewall recesses by depositing a dielectric material on sidewalls of the fin structure and in the sidewall recesses of the first ones of the dummy nanostructures using a flowable chemical vapor deposition (FCVD) process. The dielectric material may comprise nitride-based materials such as silicon nitride, or the like. An annealing process may then be performed to cure the dielectric material. After the FCVD process and the annealing process are performed, an etching process (e.g., an anisotropic etching process) may be performed to etch portions of the dielectric material. The remaining portions of the dielectric material in the sidewall recesses form the spacers in the sidewall recesses. After the formation of the spacers, the first ones of the dummy nanostructures may be replaced with gate dielectrics and gate electrodes to form replacement gates, such that a thickness of a first portion of a replacement gate that is disposed between a bottommost surface of the bottommost semiconductor nanostructure and a top surface of the fin is greater than a thickness of a portion of the replacement gates that is disposed between a top surface of each semiconductor nanostructure and a bottom surface of an adjacent semiconductor nanostructure disposed above the semiconductor nanostructure. After the formation of the replacement gates, a backside gate contact may be formed at a location where the backside gate contact is overlapped by the semiconductor nanostructures (e.g., the channel regions of the CFETs), wherein the backside gate contact contacts the first portion of the replacement gate.

Advantageous features of one or more embodiments disclosed herein may allow for the greater thickness of the first portion of the replacement gate to minimize a threshold voltage (Vₜ) change of the semiconductor device as a result of possible damage to the first portion of the replacement gate during etching processes that are used during the formation of the backside gate contact. In addition, the semiconductor nanostructures (e.g., the channel regions of the CFETs) are able to directly overlap the backside gate contact which reduces the need to provide additional routing space that would be needed if the backside gate contact was not overlapped by the semiconductor nanostructures. As a result, the channel regions of the CFETs can be designed and fabricated with larger widths for improved device speed which leads to improved device performance. In addition, the semiconductor nanostructures overlapping the backside gate contact enables increased power delivery through the backside gate contact as a result of the optimized backside gate contact positioning. Further, the use of the FCVD process to form the spacers enables consistent spacer width despite the varying thicknesses between the first portion of the replacement gate and other portions of the replacement gates. The FCVD process, the annealing process, and the etching process may allow the spacers to be formed to provide reliable isolation and prevent shorting between the replacement gates and epitaxial source/drain regions. As a result, device yield and reliability can be improved while maintaining the performance advantages of increased channel widths, enhanced routing capabilities, and optimized threshold voltage control of the semiconductor device.

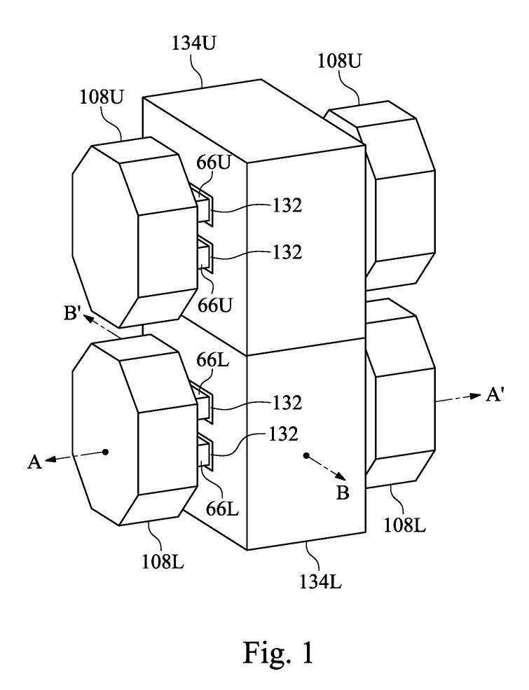

FIG. 1 illustrates an example schematic of a stacked transistor, such as a complementary field-effect transistor (CFET), in accordance with some embodiments. FIG. 1 is a three-dimensional view, where some features of the CFETs are omitted for illustration clarity.

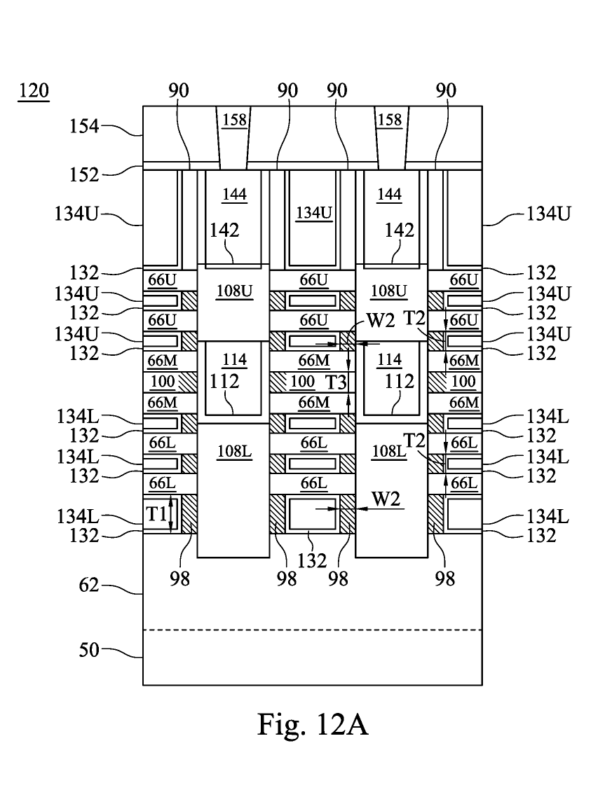

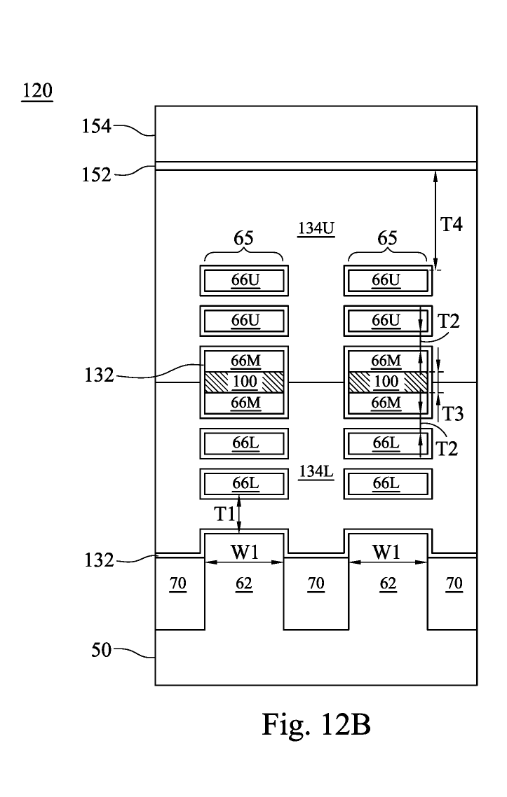

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIG. 1, see FIGS. 12A-12B) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U. Alternatively, a lower gate electrode 134L may be coupled to an upper gate electrode 134U. Further, the upper epitaxial source/drain regions 108U may be separated from lower epitaxial source/drain regions 108L by one or more dielectric layers (not explicitly illustrated in FIG. 1, see FIGS. 12A-12B). The isolation features between channel regions, gates, and source/drain regions allow for vertically stacked transistors, thereby improving device density. Because of the vertically stacked nature of CFETs, the schematic may also be referred to as stacked transistors or folding transistors.

FIG. 1 further illustrates reference cross-sections that are used in later figures. Cross-section A-A' is parallel to a longitudinal axis of the semiconductor nanostructures 66 of a CFET and in a direction of, for example, a current flow between the source/drain regions 108 of the CFET. Cross-section B-B' is perpendicular to cross-section A-A' and along a longitudinal axis of a gate electrode 134 of a CFET. Subsequent figures refer to these reference cross-sections for clarity.

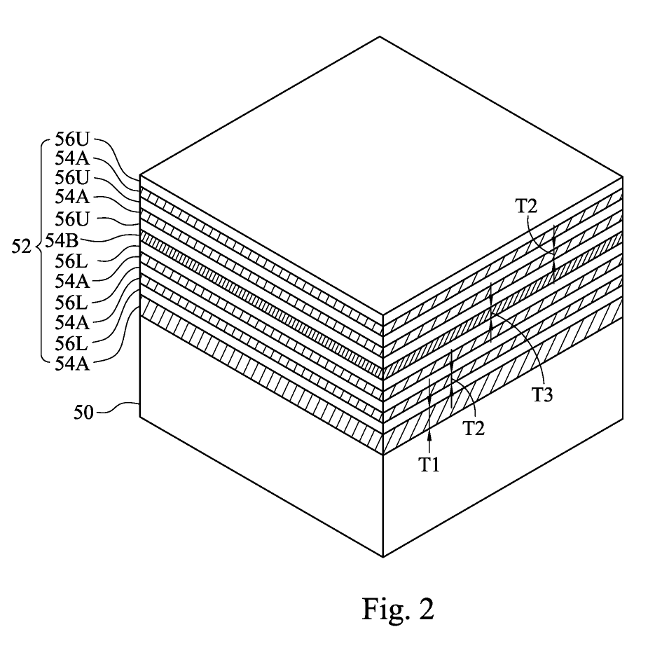

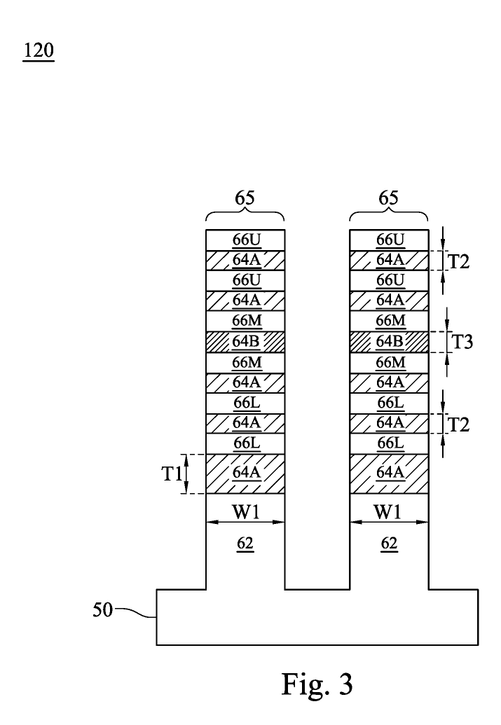

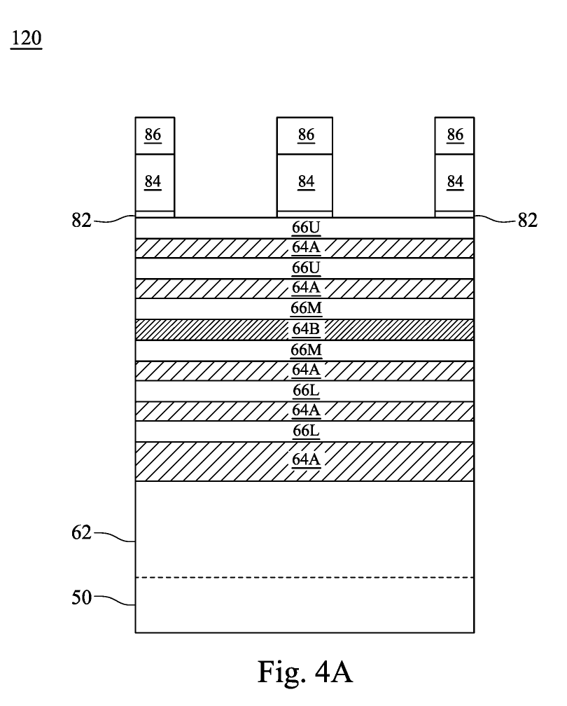

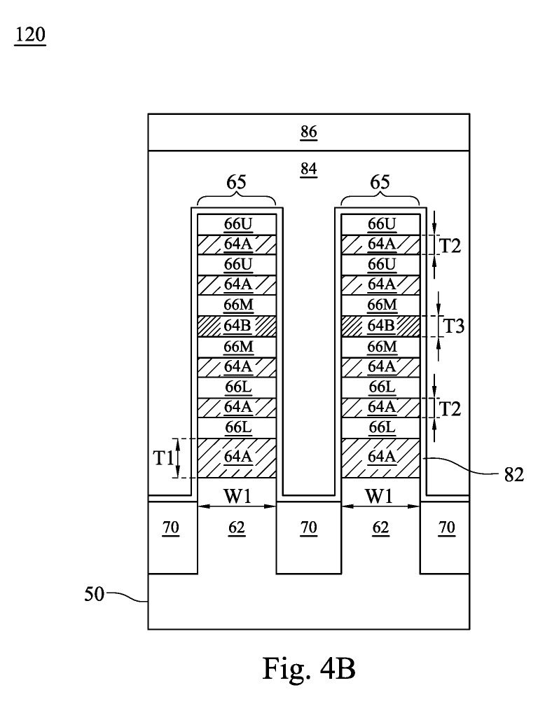

FIGS. 2-13B are views of intermediate stages in the manufacturing of a semiconductor device 120 that includes CFETs, in accordance with some embodiments. FIG. 2 is a three-dimensional view showing a similar three-dimensional view as FIG. 1. FIGS. 3, 4A, 5, 6, 7, 8, 9, 10, 11, 12A, and 13A illustrate cross-sectional views along a similar cross-section as reference cross-section A-A' in FIG. 1. FIGS. 4B, 12B, and 13B illustrates a cross-sectional view along a similar cross-section as reference cross-section B-B' in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B. The upper semiconductor layers 56U and another subset of the first dummy layers 54A are disposed above the second dummy layer 54B. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including a specific number of the dummy layers 54 and a specific number of the semiconductor layers 56. It should be appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A and the second dummy layer 54B may be formed of a first semiconductor material. The first semiconductor material may be selected from the candidate semiconductor materials of the substrate 50. In some embodiments, the dummy layers 54 (e.g., the first dummy layers 54A and the second dummy layer 54B) are formed of or comprise silicon germanium, and the second dummy layer 54B may be formed of germanium or silicon germanium with a higher germanium atomic percentage than the first dummy layers 54A. The first dummy layers 54A and the second dummy layer 54B have a high etching selectivity to one another, such that the second dummy layer 54B may be removed at a faster rate than the first dummy layers 54A in subsequent processing. The semiconductor layers 56 (including the lower semiconductor layers 56L and upper semiconductor layers 56U) are formed of a second semiconductor material that is different from the first semiconductor material. The second semiconductor material may be selected from the candidate semiconductor materials of the substrate 50. In some embodiments, the semiconductor layers 56 are formed of silicon. The semiconductor layers 56 and the dummy layers 54 have a high etching selectivity to one another, such that the dummy layers 54 (e.g., the first dummy layers 54A and the second dummy layer 54B) may be removed at a faster rate than the semiconductor layers 56 (e.g., the lower semiconductor layers 56L and the upper semiconductor layers 56U) in subsequent processing.

In an embodiment, a bottommost dummy layer of the dummy layers 54 (e.g., a bottommost first dummy layer 54A of the first dummy layers 54A) may have a thickness T1 that is in a range from 2 nm to 50 nm. In an embodiment, the first dummy layers 54A that are disposed above the bottommost first dummy layer 54A may have a thickness T2 that is in a range from 2 nm to 30 nm. In an embodiment, the second dummy layer 54B may have a thickness T3 that is in a range from 2 nm to 30 nm. In an embodiment, the thickness T1 is greater than the thickness T3, and the thickness T3 is greater than the thickness T2.

In FIG. 3, fin structures 65 are formed from the substrate 50 and the multi-layer stack 52, wherein each fin structure 65 comprises a fin 62 and nanostructures 64, 66 above the fin 62. In an embodiment, the fins 62 are formed in the substrate 50 and the nanostructures 64, 66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66. In an embodiment, during the formation of the fin structures 65, bottommost first dummy nanostructures 64A are defined from the bottommost first dummy layer 54A (shown previously in FIG. 2), wherein each bottommost first dummy nanostructure 64A may have the thickness T1 that is in a range from 2 nm to 50 nm. In an embodiment, during the formation of the fin structures 65, first dummy nanostructures 64A are defined from the first dummy layers 54A (shown previously in FIG. 2) that are disposed above the bottommost first dummy layer 54A, wherein each first dummy nanostructure 64A that is disposed above a bottommost first dummy nanostructure 64A may have the thickness T2 that is in a range from 2 nm to 30 nm. In an embodiment, during the formation of the fin structures 65, second dummy nanostructures 64B are defined from the second dummy layer 54B (shown previously in FIG. 2), wherein each second dummy nanostructure 64B may have the thickness T3 that is in a range from 2 nm to 30 nm. In an embodiment, the thickness T1 is greater than the thickness T3, and the thickness T3 is greater than the thickness T2.

As subsequently described in greater detail, various one of the nanostructures 64, 66 will be removed to form channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

The fins 62 and the nanostructures 64, 66 of the fin structures 65 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 65 (including the fins 62 and the nanostructures 64, 66). In some embodiments, a mask (or other layer) may remain on the nanostructures 64, 66.

In an embodiment, each fin structure 65 may have a width W1 that is in a range from 5 nm to 100 nm. Although each of the fin structures 65 (including the fins 62 and the nanostructures 64, 66) is illustrated as having the constant width W1 throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in shape.

In FIGS. 4A-4B, isolation regions 70 are formed over the substrate 50 and between adjacent semiconductor fins 62. The isolation regions 70 may include a liner and a fill material over the liner. Each of the liner and the fill material may include a dielectric material such as an oxide (e.g., silicon oxide), a nitride (e.g., silicon nitride), the like, or a combination thereof. The formation of the isolation regions 70 may include depositing the dielectric material(s), and performing a planarization process such as a chemical mechanical polish (CMP) process, a mechanical polishing process, or the like to remove excess portions of the dielectric material(s), such as portions over the nanostructures 64, 66. The deposition processes may include ALD, high-density plasma chemical vapor deposition (HDP-CVD), flowable chemical vapor deposition (FCVD), the like, or a combination thereof. In some embodiments, the isolation regions 70 include silicon oxide formed by an FCVD process, followed by an anneal process. Then, the dielectric material(s) are recessed to define the isolation regions 70. The dielectric material(s) maybe recessed such that upper portions of the semiconductor fins 62 and the nanostructures 64, 66 extend higher than the isolation regions 70.

The previously described process of FIGS. 3-4B is just one example of how the fin structures 65 (including the fins 62 and the nanostructures 64, 66) may be formed. In some embodiments, the fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64, 66. The epitaxial structures may comprise the previously described alternating semiconductor materials, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

Referring further to FIGS. 4A-4B, a dummy dielectric layer may be formed on the fins 62 and/or the nanostructures 64, 66. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be formed of other materials that have a high etching selectivity to insulating materials. The mask layer may include, for example, silicon nitride, silicon oxynitride, or the like. In an embodiment, the dummy dielectric layer covers the isolation regions 70, such that the dummy dielectric layer extends between the dummy gate layer and the isolation regions 70. In another embodiment, the dummy dielectric layer may cover only the fins 62 and/or the nanostructures 64, 66.

After the formation of the dummy gate layer, the dummy dielectric layer, and the mask layer, the mask layer may be patterned using acceptable photolithography and etching techniques to form masks 86. The pattern of the masks 86 then may be transferred to the dummy gate layer and to the dummy dielectric layer to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

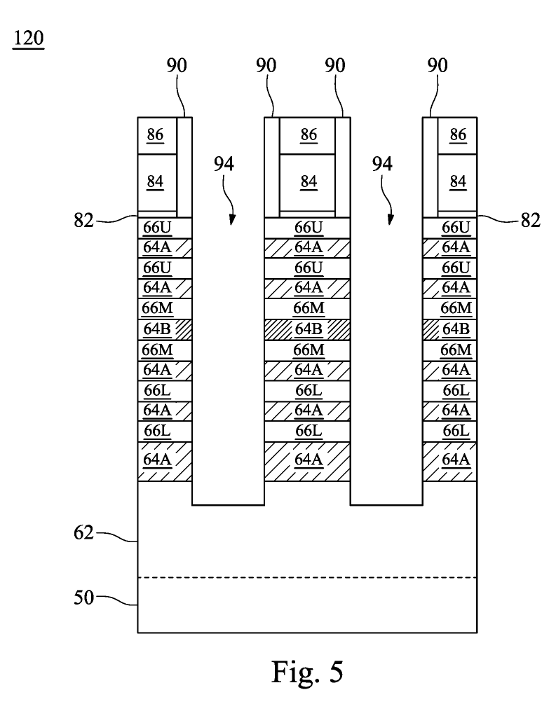

In FIG. 5, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). In some embodiments, the dielectric material(s), when etched, may also have portions left on the sidewalls of the fins 62 and/or the nanostructures 64, 66.

It is noted that the previous disclosure generally describes a process of forming spacers. Other processes and sequences may be used. For example, fewer or additional spacers may be utilized, different sequence of steps may be utilized, additional spacers may be formed and removed, and/or the like.

Source/drain recesses 94 are formed in the fins 62, the nanostructures 64, 66, and the substrate 50. Epitaxial source/drain regions will be subsequently formed in the source/drain recesses 94. The source/drain recesses 94 may extend through the nanostructures 64, 66 and into the substrate 50. The fins 62 may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be formed by etching the fins 62, the nanostructures 64, 66, and the substrate 50 using anisotropic etching processes, such as RIE, NBE, or the like. The gate spacers 90 and the dummy gates 84 mask portions of the fins 62, the nanostructures 64, 66, and the substrate 50 during the etching processes used to form the source/drain recesses 94. A single etch process or multiple etch processes may be used to etch each layer of the nanostructures 64, 66 and/or the fins 62. Timed etch processes may be used to stop the etching of the source/drain recesses 94 after the source/drain recesses 94 reach a desired depth.

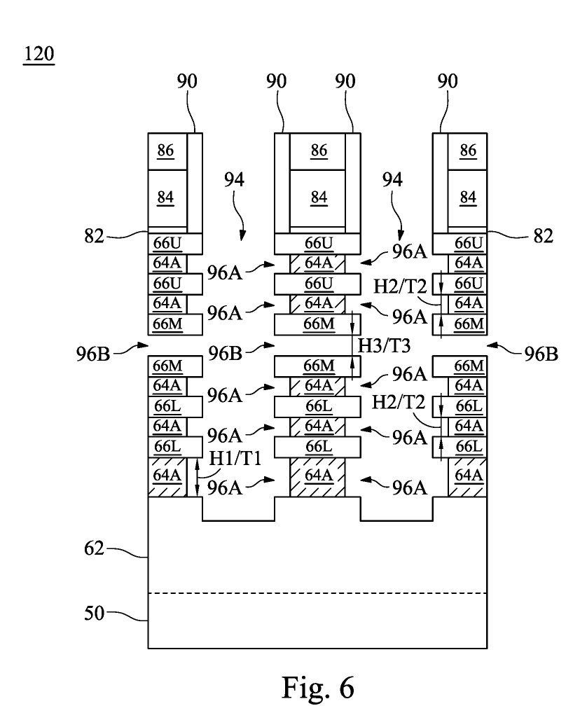

In FIG. 6, the sidewalls of the first dummy nanostructures 64A exposed by the source/drain recesses 94 are recessed to form sidewall recesses 96A. Additionally, the second dummy nanostructures 64B are removed to form openings 96B between the lower semiconductor nanostructures 66L (collectively) and the upper semiconductor nanostructures 66U (collectively). The sidewall recesses 96A will subsequently be filled with spacers. The openings 96B will subsequently be filled with isolation structures.

The sidewall recesses 96A may be formed by recessing the sidewalls of the first dummy nanostructures 64A with any acceptable etch process. The etching is selective to the first dummy nanostructures 64A (e.g., selectively etches the material of the first dummy nanostructures 64A at a faster rate than the material of the semiconductor nanostructures 66). The etching may be isotropic. Although sidewalls of the first dummy nanostructures 64A are illustrated as being straight after the etching, the sidewalls may be concave or convex.

The openings 96B may be formed by removing the second dummy nanostructures 64B with any acceptable etch process. The etching is selective to the second dummy nanostructures 64B (e.g., selectively etches the material of the second dummy nanostructures 64B at a faster rate than the material of the semiconductor nanostructures 66). The etching may be isotropic. The dummy gates 84 may adhere to and support the upper semiconductor nanostructures 66U so that the upper semiconductor nanostructures 66U do not collapse after the formation of the openings 96B.

In some embodiments, the same etching process is used to recess the sidewalls of the first dummy nanostructures 64A (including the bottommost first dummy nanostructures 64A) and to remove the second dummy nanostructures 64B. For example, the second dummy nanostructures 64B may be completely removed without completely removing the first dummy nanostructures 64A, and the first dummy nanostructures 64A may be recessed without significantly recessing the semiconductor nanostructures 66. The etching process has selectivity among the materials of the first dummy nanostructures 64A, the second dummy nanostructures 64B, and the semiconductor nanostructures 66. Specifically, the etching process selectively etches the material of the first dummy nanostructures 64A at a faster rate than the material of the semiconductor nanostructures 66, and also selectively etches the material of the second dummy nanostructures 64B at a faster rate than the selectively etches the material of the first dummy nanostructures 64A. Thus, the etch rate of the first dummy nanostructures 64A is less than the etch rate of the second dummy nanostructures 64B and is greater than the etch rate of the semiconductor nanostructures 66. In some embodiments where the second dummy nanostructures 64B are formed of germanium or silicon germanium with a high germanium atomic percentage, the first dummy nanostructures 64A are formed of silicon germanium with a low germanium atomic percentage, and the semiconductor nanostructures 66 are formed of silicon free from germanium, the etch process may comprise a dry etch process using chlorine gas, with or without a plasma. In an embodiment, each sidewall recess 96A that is formed in the bottommost first dummy nanostructures 64A may have a height H1 that is equal to the thickness T1. In an embodiment, each sidewall recess 96A that is formed in the first dummy nanostructures 64A that are disposed above the bottommost first dummy nanostructures 64A may have a height H2 that is equal to the thickness T2. In an embodiment, each of the openings 96B may have a height H3 that is equal to the thickness T3, wherein the height H1 is greater than the height H3, and the height H3 is greater than the height H2.

The middle semiconductor nanostructures 66M are exposed by the openings 96B. In some embodiments, the etching process thins the middle semiconductor nanostructures 66M. Accordingly, the thickness of the middle semiconductor nanostructures 66M may be different (e.g., less than) the thickness of the lower semiconductor nanostructures 66L and the thickness of the upper semiconductor nanostructures 66U. In some embodiments, the middle semiconductor nanostructures 66M are from 0% to 20% thinner than the lower semiconductor nanostructures 66L and the upper semiconductor nanostructures 66U after the etching process.

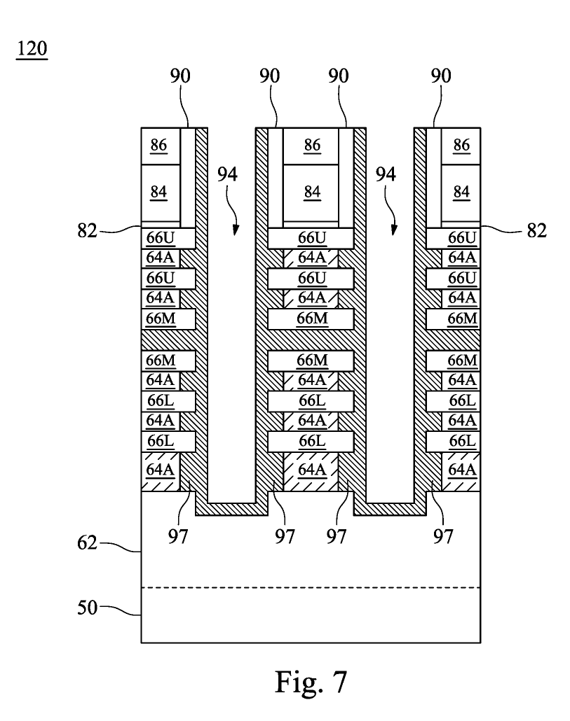

In FIG. 7, a dielectric material 97 is deposited in the source/drain recesses 94 such as on bottom surfaces and sidewalls of the source/drain recesses 94. For example, the dielectric material 97 may be formed in the sidewall recesses 96A and on the sidewalls of the semiconductor nanostructures 66. The dielectric material 97 may also be formed to fill the openings 96B. In an embodiment, the dielectric material 97 may also be formed on sidewalls of the gate spacers 90. As shown in FIG. 7, excess dielectric material 97 may extend laterally beyond the sidewall recesses 96A and the openings 96B.

In an embodiment, the dielectric material 97 may comprise a nitride such as, for example, silicon nitride, silicon oxycarbonitride, silicon oxynitride, or the like, that is deposited using a flowable chemical vapor deposition (FCVD) process. In an embodiment, the FCVD process may comprise exposing sidewalls of the gate spacers 90, bottom surfaces of the source/drain recesses 94, sidewalls of the remaining portions of the first dummy nanostructures 64A in the source/drain recesses 94, sidewalls of the semiconductor nanostructures 66 in the source/drain recesses 94, and surfaces of the semiconductor nanostructures 66 that define the openings 96B to a silicon-containing precursor and a nitrogen-containing precursor. In some embodiments, the silicon-containing precursor is a polysilazane. Polysilazanes are polymers having a basic structure composed of silicon and nitrogen atoms in an alternating sequence. In polysilazanes, each silicon atom is usually bound to two nitrogen atoms, or each nitrogen atom is bound to two silicon atoms, so that these can be described predominantly as molecular chains of the formula [R₁R₂Si—NR₃]ₙ. R₁-R₃ can be hydrogen atoms or organic substituents. In some embodiments, the silicon-containing precursor is a silylamine, such as trisilylamine (TSA), disilylamine (DSA), or a combination thereof. One or more carrier gases may also be included with the silicon-containing precursor. The carrier gases may include helium (He), argon (Ar), nitrogen (N₂), the like, or a combination thereof.

The nitrogen-containing precursor may include NH₃, N₂, the like, or a combination thereof. In some embodiments, the nitrogen-containing precursor is activated into plasma in a remote plasma system (RPS) outside of the deposition chamber. An oxygen source gas, such as O₂ or the like may be included with the nitrogen-containing precursor and activated into plasma in the RPS. Plasma generated in the RPS is carried into the deposition chamber by a carrier gas, which includes He, Ar, N₂, the like, or a combination thereof, in some embodiments.

The silicon-containing precursor and the nitrogen-containing precursor mix and react to deposit the dielectric material 97 containing silicon and nitrogen in the sidewall recesses 96A, on the sidewalls of the semiconductor nanostructures 66, in the openings 96B, and on the sidewalls of the gate spacers 90.

After the deposition of the dielectric material 97, an annealing process may be performed to cure the dielectric material 97. The annealing process may comprise exposing the dielectric material 97 to a temperature that may be in a range from 300° C to 700° C in an environment containing nitrogen (N₂), oxygen (O₂), hydrogen (H₂), helium (He), argon (Ar), the like, or a combination thereof. During the annealing process, the dielectric material 97 may be densified.

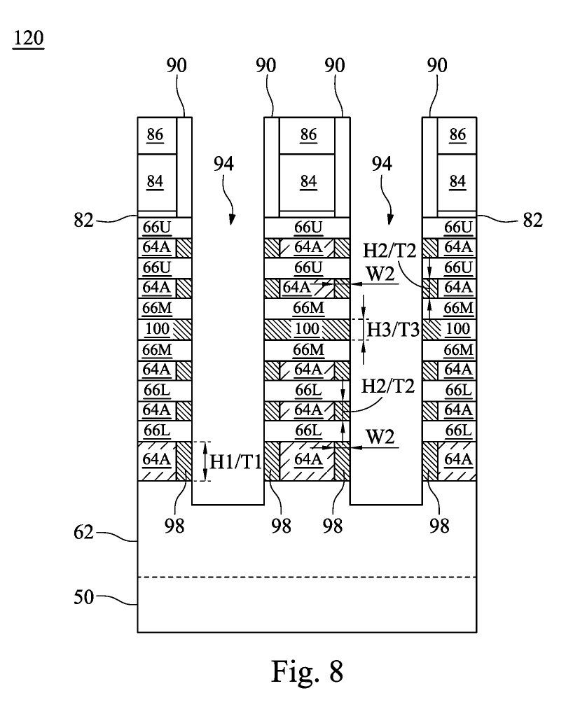

In FIG. 8, After the FCVD process and the annealing process are performed, an etching process is performed to etch the dielectric material 97 to form inner spacers 98 in the sidewall recesses 96A and on the sidewalls of the remaining portions of the first dummy nanostructures 64A. In addition, during the performing of the etching process, isolation structures 100 are formed in the openings 96B and between the middle semiconductor nanostructures 66M.

As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to form gate structures. Additionally, the isolation structures 100 and the middle semiconductor nanostructures 66M will define the boundaries of the lower nanostructure-FETs and the upper nanostructure-FETs.

The etching process may be for example, an anisotropic etching process that comprises a dry etch process such as a reactive ion etch (RIE) or a neutral beam etch (NBE). The etching process removes excess portions of the dielectric material 97 while maintaining the material within the sidewall recesses 96A and the openings 96B, resulting in well-defined inner spacers 98 and isolation structures 100.

Although outer sidewalls of the inner spacers 98 and the isolation structures 100 are illustrated as being flush with sidewalls of the semiconductor nanostructures 66, the outer sidewalls of the inner spacers 98 and the isolation structures 100 may extend beyond or be recessed from sidewalls of the semiconductor nanostructures 66. Thus, the inner spacers 98 and the isolation structures 100 may partially fill, completely fill, or overfill the sidewall recesses 96A and the openings 96B, respectively. Moreover, although the sidewalls of the inner spacers 98 and the isolation structures 100 are illustrated as being straight, those sidewalls may be concave or convex.

The isolation structures 100 have similar dimensions as the second dummy nanostructures 64B they replaced. Accordingly, the isolation structures 100 may have a large thickness, such as a greater thickness than the semiconductor nanostructures 66. In an embodiment, each of the isolation structures 100 may have the thickness T3 that is in a range from 2 nm to 30 nm. In an embodiment, each inner spacer 98 that is formed in a corresponding sidewall recess 96A in the bottommost first dummy nanostructures 64A may have the thickness T1 that is in the range from 2 nm to 50 nm. In an embodiment, each inner spacer 98 that is formed in a corresponding sidewall recess 96A in the first dummy nanostructures 64A that are disposed above the bottommost first dummy nanostructures 64A may have the thickness T2 that is in the range from 2 nm to 30 nm. In an embodiment, the thickness T1 is greater than the thickness T3, and the thickness T3 is greater than the thickness T2. In an embodiment, a width of each of the inner spacers 98 that is formed in a corresponding sidewall recess 96A in the bottommost first dummy nanostructures 64A may be equal to a width W2. In addition, a width of each of the inner spacers 98 that is formed in a corresponding sidewall recess 96A in the first dummy nanostructures 64A that are disposed above the bottommost first dummy nanostructures 64A may be equal to the width W2, wherein the width W2 may be in a range from 2 nm to 20 nm. In an embodiment, each inner spacer 98 that is formed in a corresponding sidewall recess 96A in the bottommost first dummy nanostructures 64A may have a uniform width W2 in a direction from a top surface of the inner spacer 98 to a bottom surface of the inner spacer 98.

Advantages can be achieved by depositing the dielectric material 97 in the source/drain recesses 94 using the FCVD process described previously in FIG. 7 such as in the sidewall recesses 96A, in the openings 96B, and on the sidewalls of the semiconductor nanostructures 66. The annealing process described previously in FIG. 7 is then performed to cure the dielectric material 97, and the etching process described in FIG. 8 is performed to etch the dielectric material 97 to form inner spacers 98 in the sidewall recesses 96A and on the sidewalls of the remaining portions of the first dummy nanostructures 64A (including the bottommost first dummy nanostructures 64A), and the isolation structures 100 in the openings 96B between the middle semiconductor nanostructures 66M. These advantages include the ability to form the inner spacers 98 having a uniform width W2 despite the inner spacers 98 that are formed in corresponding sidewall recesses 96A in the bottommost first dummy nanostructures 64A having the thickness T1 that is greater than the thickness T2 of the inner spacers 98 that are formed in corresponding sidewall recesses 96A in the first dummy nanostructures 64A that are disposed above the bottommost first dummy nanostructures 64A. The inner spacers 98 are therefore able to be formed to provide adequate isolation and prevent shorting between subsequently formed replacement gates and subsequently formed epitaxial source/drain regions. As a result, device yield and reliability can be improved.

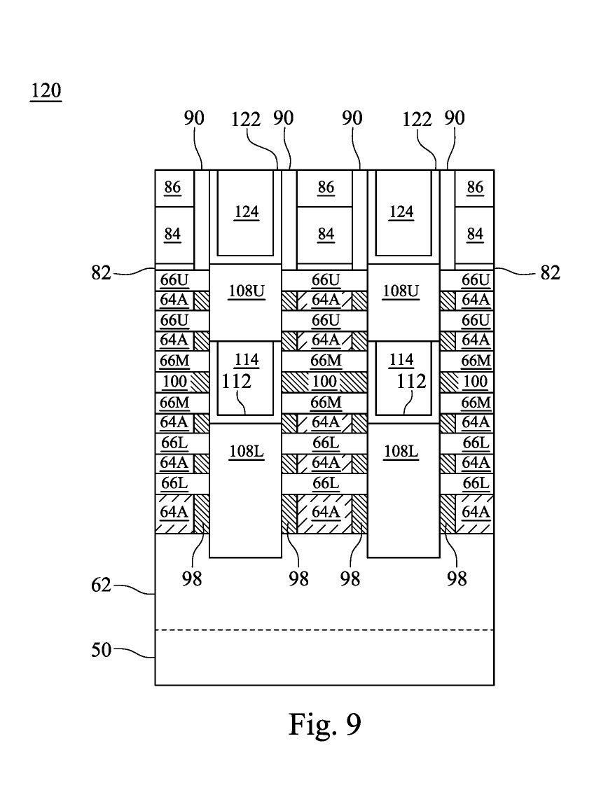

In FIG. 9, lower epitaxial source/drain regions 108L and upper epitaxial source/drain regions 108U are formed in the source/drain recesses 94. A first contact etch stop layer (CESL) 112 and/or a first inter-layer dielectric (ILD) 114 may also be formed in the source/drain recesses 94. The first ILD 114 is between the upper epitaxial source/drain regions 108U and the lower epitaxial source/drain regions 108L. The lower epitaxial source/drain regions 108L are for lower nanostructure-FETs of the CFETs, and the upper epitaxial source/drain regions 108U are for upper nanostructure-FETs of the CFETs. The first ILD 114 thus acts as isolation regions to prevent shorting of the lower and upper nanostructure-FETs. Additionally, a second CESL 122 and/or a second ILD 124 may be formed on the upper epitaxial source/drain regions 108U.

The lower epitaxial source/drain regions 108L are in contact with the lower semiconductor nanostructures 66L and are not in contact with the upper semiconductor nanostructures 66U. In some embodiments, the lower epitaxial source/drain regions 108L exert stress in the respective channel regions of the lower semiconductor nanostructures 66L, thereby improving performance. The lower epitaxial source/drain regions 108L are formed in the source/drain recesses 94 such that each stack of the lower semiconductor nanostructures 66L is disposed between respective neighboring pairs of the lower epitaxial source/drain regions 108L. In some embodiments, the inner spacers 98 are used to separate the lower epitaxial source/drain regions 108L from the first dummy nanostructures 64A (including the bottommost first dummy nanostructures 64A), which will be replaced with gate structures in subsequent processes.

The lower epitaxial source/drain regions 108L are epitaxially grown in the lower portions of the source/drain recesses 94. For example, the lower epitaxial source/drain regions 108L may be grown laterally from exposed sidewalls of the lower semiconductor nanostructures 66L. During the epitaxy of the lower epitaxial source/drain regions 108L, the middle semiconductor nanostructures 66M and/or the upper semiconductor nanostructures 66U may be masked to prevent undesired epitaxial growth on the middle semiconductor nanostructures 66M and/or the upper semiconductor nanostructures 66U. After the lower epitaxial source/drain regions 108L are grown, the masks on the middle semiconductor nanostructures 66M and/or the upper semiconductor nanostructures 66U may then be removed. The lower epitaxial source/drain regions 108L have a conductivity type that is suitable for the device type of the lower nanostructure-FETs. In some embodiments, the lower epitaxial source/drain regions 108L are n-type source/drain regions. For example, if the lower semiconductor nanostructures 66L are silicon, the lower epitaxial source/drain regions 108L may include materials exerting a tensile strain on the lower semiconductor nanostructures 66L, such as silicon, carbon-doped silicon, phosphorous-doped silicon, silicon phosphide, silicon arsenide, or the like. In some embodiments, the lower epitaxial source/drain regions 108L are p-type source/drain regions. For example, if the lower semiconductor nanostructures 66L are silicon-germanium, the lower epitaxial source/drain regions 108L may include materials exerting a compressive strain on the lower semiconductor nanostructures 66L, such as silicon-germanium, boron-doped silicon-germanium, boron-doped silicon, germanium, germanium tin, or the like. The lower epitaxial source/drain regions 108L may have surfaces raised from respective upper surfaces of the lower semiconductor nanostructures 66L and may have facets.

The lower epitaxial source/drain regions 108L may be implanted with dopants to form source/drain regions, followed by an anneal. The source/drain regions may have an impurity concentration in the range of 10¹⁹ atoms/cm³ and 10²¹ atoms/cm³. For example, an n-type impurity implant or a p-type impurity implant may be performed. The n-type impurities may be phosphorus, arsenic, antimony, or the like. The p-type impurities may be boron, boron fluoride, indium, or the like. In some embodiments, the lower epitaxial source/drain regions 108L are in situ doped during epitaxial growth.

As a result of the epitaxy processes used to form the lower epitaxial source/drain regions 108L, upper surfaces of the lower epitaxial source/drain regions 108L have facets which expand laterally outward beyond sidewalls of the nanostructures 64, 66. In some embodiments, adjacent lower epitaxial source/drain regions 108L remain separated after the epitaxy process is completed. In other embodiments, these facets cause adjacent lower epitaxial source/drain regions 108L of a same nanostructure-FET to merge.

The first ILD 114 is formed over the lower epitaxial source/drain regions 108L. The first ILD 114 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The first CESL 112 may be formed between the first ILD 114 and the lower epitaxial source/drain regions 108L. The first CESL 112 may be formed of a dielectric material having a high etching selectivity to the dielectric material of the first ILD 114, such as silicon nitride, silicon oxide, silicon oxynitride, or the like, which may be formed by any suitable deposition process, such as CVD, ALD, or the like.

The first CESL 112 and/or the first ILD 114 may be formed by depositing a material for the first CESL 112 and depositing a material for the first ILD 114, followed by an etch-back process. In some embodiments, the first ILD 114 is initially etched, leaving the first CESL 112 unetched. An anisotropic etching process is then performed to remove the portions of the first CESL 112 that are higher than the first ILD 114. After the recessing, the sidewalls of the upper semiconductor nanostructures 66U are exposed.

The upper epitaxial source/drain regions 108U are in contact with the upper semiconductor nanostructures 66U and are not in contact with the lower semiconductor nanostructures 66L. In some embodiments, the upper epitaxial source/drain regions 108U exert stress in the respective channel regions of the upper semiconductor nanostructures 66U, thereby improving performance. The upper epitaxial source/drain regions 108U are formed in the source/drain recesses 94 such that each stack of the upper semiconductor nanostructures 66U is disposed between respective neighboring pairs of the upper epitaxial source/drain regions 108U. In some embodiments, the inner spacers 98 are used to separate the upper epitaxial source/drain regions 108U from the first dummy nanostructures 64A, which will be replaced with gate structures in subsequent processes.

The upper epitaxial source/drain regions 108U are epitaxially grown in the upper portions of the source/drain recesses 94. For example, the upper epitaxial source/drain regions 108U may be grown laterally from exposed sidewalls of the upper semiconductor nanostructures 66U. The upper epitaxial source/drain regions 108U have a conductivity type that is suitable for the device type of the upper nanostructure-FETs. The conductivity type of the upper epitaxial source/drain regions 108U may be opposite the conductivity type of the lower epitaxial source/drain regions 108L. Put another way, the upper epitaxial source/drain regions 108U may be oppositely doped from the lower epitaxial source/drain regions 108L. In some embodiments, the upper epitaxial source/drain regions 108U are n-type source/drain regions. For example, if the upper semiconductor nanostructures 66U are silicon, the upper epitaxial source/drain regions 108U may include materials exerting a tensile strain on the upper semiconductor nanostructures 66U, such as silicon, carbon-doped silicon, phosphorous-doped silicon, silicon phosphide, silicon arsenide, or the like. In some embodiments, the upper epitaxial source/drain regions 108U are p-type source/drain regions. For example, if the upper semiconductor nanostructures 66U are silicon-germanium, the upper epitaxial source/drain regions 108U may include materials exerting a compressive strain on the upper semiconductor nanostructures 66U, such as silicon-germanium, boron-doped silicon-germanium, boron-doped silicon, germanium, germanium tin, or the like. The upper epitaxial source/drain regions 108U may have surfaces raised from respective upper surfaces of the upper semiconductor nanostructures 66U and may have facets.

The upper epitaxial source/drain regions 108U may be implanted with dopants to form source/drain regions, followed by an anneal. The source/drain regions may have an impurity concentration in the range of 10¹⁹ atoms/cm³ and 10²¹ atoms/cm³. The n-type impurities may be phosphorus, arsenic, antimony, or the like. The p-type impurities may be boron, boron fluoride, indium, or the like. In some embodiments, the upper epitaxial source/drain regions 108U are in situ doped during epitaxial growth.

As a result of the epitaxy processes used to form the upper epitaxial source/drain regions 108U, upper surfaces of the upper epitaxial source/drain regions 108U have facets which expand laterally outward beyond sidewalls of the nanostructures 64, 66. In some embodiments, adjacent upper epitaxial source/drain regions 108U remain separated after the epitaxy process is completed. In other embodiments, these facets cause adjacent upper epitaxial source/drain regions 108U of a same nanostructure-FET to merge.

The second ILD 124 is deposited over the upper epitaxial source/drain regions 108U. The second ILD 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The second CESL 122 may be formed between the second ILD 124 and the upper epitaxial source/drain regions 108U. The second CESL 122 may be formed of a dielectric material having a high etching selectivity to the dielectric material of the second ILD 124, such as, silicon nitride, silicon oxide, silicon oxynitride, or the like, which may be formed by any suitable deposition process, such as CVD, ALD, or the like.

The second CESL 122 and/or the second ILD 124 may be formed by depositing a material for the second CESL 122 and depositing a material for the second ILD 124. A removal process is then performed to level the top surfaces of the second ILD 124 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the second ILD 124, the gate spacers 90, and the masks 86 (if present) or the dummy gates 84 are substantially coplanar (within process variations). Accordingly, the top surfaces of the masks 86 (if present) or the dummy gates 84 are exposed through the second ILD 124. In the illustrated embodiment, the masks 86 remain after the removal process. In other embodiments, the masks 86 are removed such that the top surfaces of the dummy gates 84 are exposed through the second ILD 124.

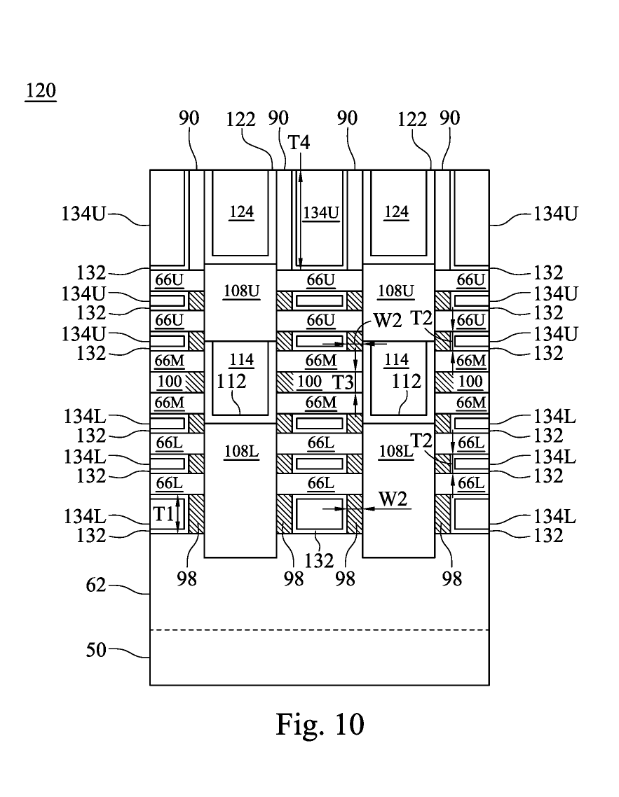

In FIG. 10, the dummy gates 84 are removed in one or more etching steps, so that recesses are formed between the gate spacers 90. Portions of the dummy dielectrics 82 in the recesses are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the second ILD 124, the isolation structures 100, the inner spacers 98, and the gate spacers 90. Each recess between the gate spacers 90 exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A (including the bottommost first dummy nanostructures 64A) are then removed to form openings in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon nitride, and the isolation structures 100 are formed of silicon nitride, the etch process may be a wet etch using tetramethylammonium hydroxide (TMAH), ammonium hydroxide (NH4OH), or the like. In some embodiments, a trim process (not separately illustrated) is performed to decrease the thicknesses of the exposed portions of the semiconductor nanostructures 66 and expand the openings between the semiconductor nanostructures 66.

Next, gate dielectrics 132 and gate electrodes 134 (including lower gate electrodes 134L and upper gate electrodes 134U) are formed for replacement gates. Each respective pair of a gate dielectric 132 and a gate electrode 134 (including an upper gate electrode 134U and/or a lower gate electrode 134L) may be collectively referred to as a “gate structure” or a “gate stack”. Each gate structure extends along at least three sides (e.g., a top surface, a sidewall, and a bottom surface) of a channel region of a semiconductor nanostructure 66. The gate structures may also extend along sidewalls and/or a top surface of a semiconductor fin 62.

The gate dielectrics 132 include one or more gate dielectric layer(s) disposed around the lower semiconductor nanostructures 66L, the upper semiconductor nanostructures 66U, and the isolation structures 100. Specifically, the gate dielectrics 132 are disposed on the top surfaces of the fins 62; on the top surfaces, the sidewalls, and the bottom surfaces of the semiconductor nanostructures 66; and on the sidewalls of the gate spacers 90. The gate dielectrics 132 wrap around all (e.g., four) sides of the semiconductor nanostructures 66. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer.

The lower gate electrodes 134L include one or more gate electrode layer(s) disposed over the gate dielectrics 132 and around the lower semiconductor nanostructures 66L. The lower gate electrodes 134L are disposed in the lower portions of the recesses between the gate spacers 90 and in the openings between the lower semiconductor nanostructures 66L, as well as in the openings between the top surfaces of the fin 62 and bottom surfaces of bottommost ones of the lower semiconductor nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a fill material.

The lower gate electrodes 134L are formed of material(s) that are suitable for the device type of the lower nanostructure-FETs. For example, the lower gate electrodes 134L may include one or more work function tuning layer(s) formed of work function tuning metal(s) that are suitable for the device type of the lower nanostructure-FETs. In some embodiments, the lower gate electrodes 134L include an n-type work function tuning layer, which may be formed of an n-type work function tuning metal such as titanium aluminum, titanium aluminum carbide, tantalum aluminum, tantalum carbide, combinations thereof, or the like. In some embodiments, the lower gate electrodes 134L include a p-type work function tuning layer, which may be formed of a p-type work function tuning metal such as titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The upper gate electrodes 134U include one or more gate electrode layer(s) disposed over the gate dielectrics 132 and around the upper semiconductor nanostructures 66U. The upper gate electrodes 134U are disposed in the upper portions of the recesses between the gate spacers 90 and in the openings between the upper semiconductor nanostructures 66U. The upper gate electrodes 134U may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the upper gate electrodes 134U may include any number of work function tuning layers, any number of barrier layers, any number of glue layers, and a fill material.

The upper gate electrodes 134U are formed of material(s) that are suitable for the device type of the upper nanostructure-FETs. For example, the upper gate electrodes 134U may include one or more work function tuning layer(s) formed of work function tuning metal(s) that are suitable for the device type of the upper nanostructure-FETs. In some embodiments, the upper gate electrodes 134U include an n-type work function tuning layer, which may be formed of an n-type work function tuning metal such as titanium aluminum, titanium aluminum carbide, tantalum aluminum, tantalum carbide, combinations thereof, or the like. In some embodiments, the upper gate electrodes 134U include a p-type work function tuning layer, which may be formed of a p-type work function tuning metal such as titanium nitride, tantalum nitride, combinations thereof, or the like. The work function tuning metal(s) of the upper gate electrodes 134U may be different than the work function tuning metal(s) of the lower gate electrodes 134L. Additionally or alternatively, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 134U may be different than the dipole-inducing elements of the lower gate electrodes 134L.

In some embodiments, isolation layers (not separately illustrated) are formed between the lower gate electrodes 134L and the upper gate electrodes 134U. The isolation layers act as isolation features between the lower gate electrodes 134L and the upper gate electrodes 134U. The isolation layers may be formed of a dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. In embodiments where the isolation layers are formed, the isolation layers and the isolation structures 100 together isolate the upper gate electrodes 134U from the lower gate electrodes 134L. Accordingly, an upper nanostructure-FET may be isolated from a lower nanostructure-FET by a combination of an isolation structure 100 and an isolation layer. In some embodiments where the isolation layers are omitted, an upper nanostructure-FET may be coupled to a lower nanostructure-FET. When the isolation layers are omitted, the lower gate electrodes 134L may be physically and electrically coupled to the upper gate electrodes 134U.

As an example to form the gate structures, one or more gate dielectric layer(s) may be deposited in the recesses between the gate spacers 90 and the openings between the semiconductor nanostructures 66. The gate dielectric layer(s) may also be deposited on the top surfaces of the second ILD 124 and the gate spacers 90. Subsequently, one or more lower gate electrode layer(s) may be deposited on the gate dielectric layer(s), and in the remaining portions of the recesses between the gate spacers 90 and the openings between the semiconductor nanostructures 66. The lower gate electrode layer(s) may then be recessed. Any acceptable etch process, such as a dry etch, a wet etch, the like, or a combination thereof, may be performed to recess the lower gate electrode layer(s). The etching may be isotropic, such as an etch-back process that removes the lower gate electrode layer(s) from the upper portions of the recesses between the gate spacers 90, such that the lower gate electrode layer(s) remain in the openings between the lower semiconductor nanostructures 66L. In embodiments where the isolation layers are formed, an isolation material is conformally formed on the lower gate electrode layer(s) and then recessed. Any acceptable etch process, such as a dry etch, a wet etch, the like, or a combination thereof, may be performed to recess the isolation material. Subsequently, one or more upper gate electrode layer(s) may be deposited on the isolation material (if present) or the lower gate electrode layer(s), and in the remaining portions of the recesses between the gate spacers 90 and the openings between the upper semiconductor nanostructures 66U. A removal process is performed to remove the excess portions of the upper gate electrode layer(s), which excess portions are over the top surfaces of the gate spacers 90 and the second ILD 124, such that the upper gate electrode layer(s) remain in the openings between the upper semiconductor nanostructures 66U. In some embodiments, a planarization process such as a chemical mechanical polish (CMP), an etch-back process, combinations thereof, or the like may be utilized. The gate dielectric layer(s), after the removal process, have portions remaining in the recesses between the gate spacers 90 and the openings between the semiconductor nanostructures 66 (thus forming the gate dielectrics 132). The lower gate electrode layer(s), after the removal process, have portions left in the lower portions of the recesses between the gate spacers 90 and in the openings between the lower semiconductor nanostructures 66L (thus forming the lower gate electrodes 134L). The upper gate electrode layer(s), after the removal process, have portions left in the upper portions of the recesses between the gate spacers 90 and in the openings between the upper semiconductor nanostructures 66U (thus forming the upper gate electrodes 134U). When a planarization process is utilized, the top surfaces of the gate spacers 90, the second ILD 124, the gate dielectrics 132, and the upper gate electrodes 134U are coplanar (within process variations).

In an embodiment, after the formation of the gate dielectrics 132 and the gate electrodes 134 to form a gate structure 132/134L that comprises the gate dielectrics 132 and the lower gate electrode 134L, and the gate structure 132/134U that comprises the gate dielectrics 132 and the upper gate electrode 134U, first portions of the gate structure 132/134L may be disposed between top surfaces of the fin 62 and bottom surfaces of bottommost ones of the lower semiconductor nanostructures 66L, wherein each first portion of the gate structure 132/134L may have the thickness T1 that is in a range from 2 nm to 50 nm. In an embodiment, a second portion of the gate structure 132/134L or the gate structure 132/134U may be disposed between a top surface of each semiconductor nanostructure 66 and a corresponding bottom surface of an adjacent semiconductor nanostructure 66 that is disposed above the semiconductor nanostructure 66, wherein each second portion of the gate structure 132/134L or the gate structure 132/134U may have the thickness T2 that is in a range from 2 nm to 30 nm, and wherein the thickness T1 is greater than the thickness T2. In an embodiment, first portions of the gate structure 132/134U may be disposed between sidewalls of the gate spacers 90 and above topmost surfaces of topmost ones of the upper semiconductor nanostructures 66U, wherein each first portion of the gate structure 132/134U may have a thickness T4. In an embodiment, the thickness T4 is equal to the thickness T1 of the first portion of the gate structure 132/134L.

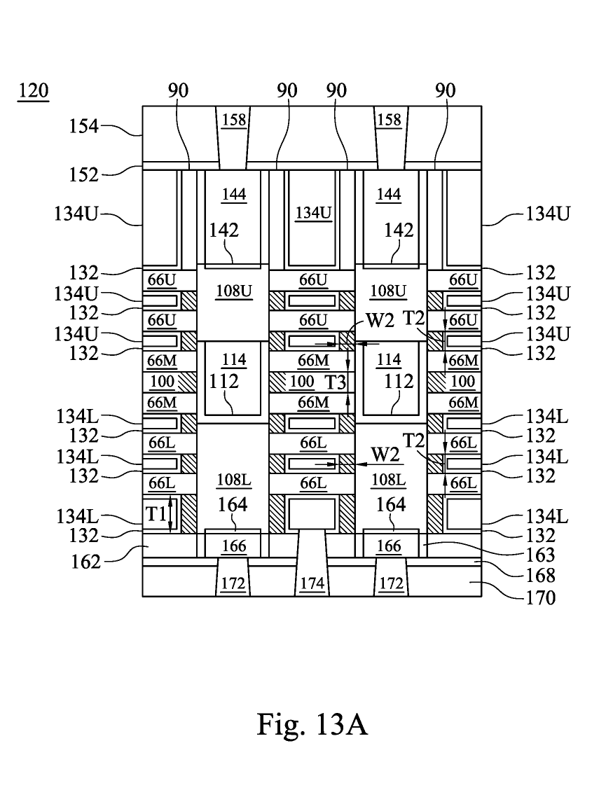

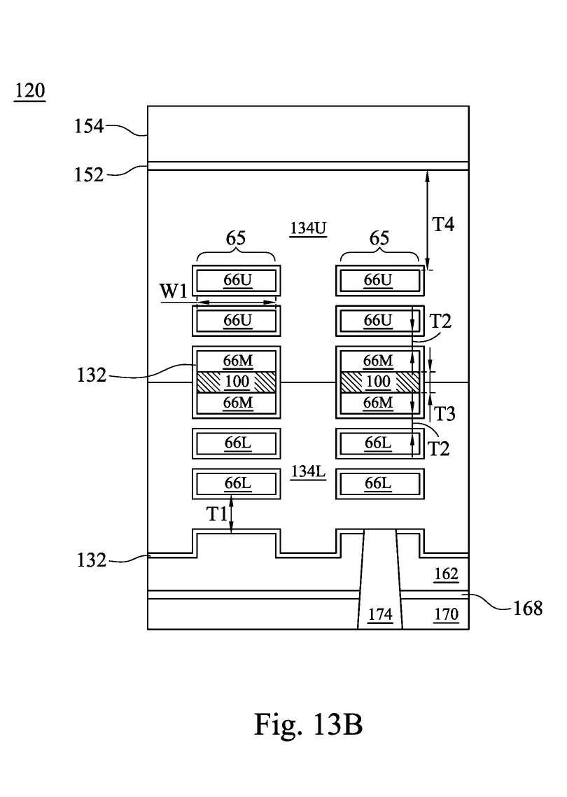

Advantages can be achieved by forming the first portions of the gate structure 132/134L that are disposed between the top surfaces of the fin 62 and the bottom surfaces of bottommost ones of the lower semiconductor nanostructures 66L, wherein each first portion of the gate structure 132/134L has the thickness T1 that is in a range from 2 nm to 50 nm. In addition, a second portion of the gate structure 132/134L or the gate structure 132/134U is formed between a top surface of each semiconductor nanostructure 66 and a corresponding bottom surface of an adjacent semiconductor nanostructure 66 that is disposed above the semiconductor nanostructure 66, wherein each second portion of the gate structure 132/134L or the gate structure 132/134U may have the thickness T2 that is in a range from 2 nm to 30 nm, and wherein the thickness T1 is greater than the thickness T2. These advantages include the greater thickness T1 of the first portion of the gate structure 132/134L minimizing threshold voltage (Vt) changes of the semiconductor device 120 as a result of possible damage to the first portion of the gate structure 132/134L during subsequent etching processes that are used during the formation of backside gate contacts 174 (shown in FIGS. 13A-13B). For example, the first portion of the gate structure 132/134L having a thickness that is smaller than 15 nm would potentially result in increased threshold voltage (Vt) variation and reduced device performance.

Further advantages can be achieved by forming the first portions of the gate structure 132/134L that are disposed between the top surfaces of the fin 62 and the bottom surfaces of bottommost ones of the lower semiconductor nanostructures 66L, wherein each first portion of the gate structure 132/134L has the thickness T1 that is in a range from 2 nm to 50 nm. In addition, the first portions of the gate structure 132/134U are also formed between sidewalls of the gate spacers 90 and above topmost surfaces of topmost ones of the upper semiconductor nanostructures 66U, wherein each first portion of the gate structure 132/134U may have the thickness T4, and the thickness T4 is equal to the thickness T1. These advantages include allowing a more balanced threshold voltage control and uniform switching characteristics of the nanostructure-FETs of the semiconductor device 120. As a result, symmetrical device operation can be achieved.

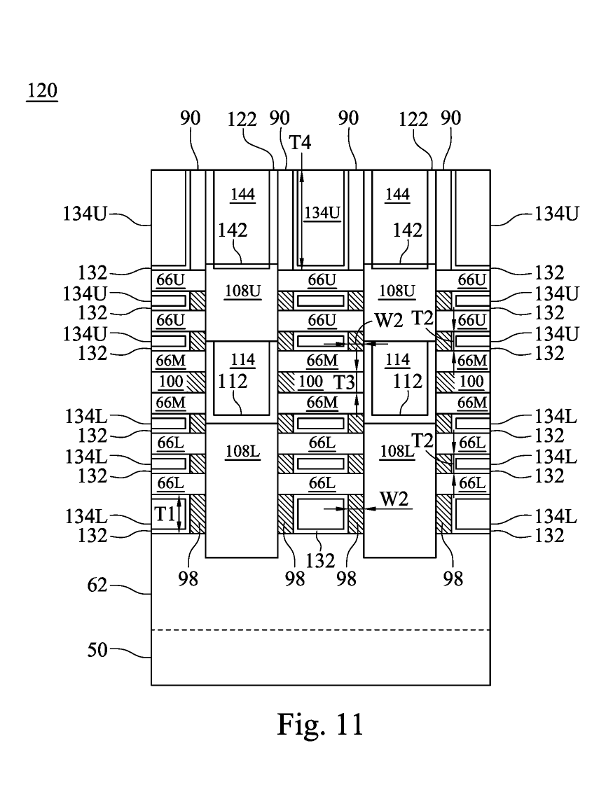

In FIG. 11, source/drain contacts 144 are formed through the second ILD 124 to electrically couple to the upper epitaxial source/drain regions 108U and/or the lower epitaxial source/drain regions 108L. As an example to form the source/drain contacts 144, openings for the source/drain contacts 144 are formed through the second ILD 124 and the second CESL 122. The openings may be formed using acceptable photolithography and etching techniques. In the illustrated embodiment, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 90, the second ILD 124 (see FIG. 10), and the upper gate electrodes 134U. The remaining liner and conductive material form the source/drain contacts 144 in the openings. In some embodiments, a planarization process such as a chemical mechanical polish (CMP), an etch-back process, combinations thereof, or the like is utilized. After the planarization process, the top surfaces of the gate spacers 90, the second ILD 124 (see FIG. 10), the upper gate electrodes 134U, and the source/drain contacts 144 are substantially coplanar (within process variations).

Optionally, metal-semiconductor alloy regions 142 are formed at the interfaces between the source/drain regions 108 and the source/drain contacts 144. The metal-semiconductor alloy regions 142 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 142 can be formed before the material(s) of the source/drain contacts 144 by depositing a metal in the openings for the source/drain contacts 144 and then performing a thermal anneal process. The metal can be any metal capable of reacting with the semiconductor materials (e.g., silicon, silicon-germanium, germanium, etc.) of the source/drain regions 108 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 144, such as from surfaces of the metal-semiconductor alloy regions 142. The material(s) of the source/drain contacts 144 can then be formed on the metal-semiconductor alloy regions 142.

In FIGS. 12A-12B, a third ILD 154 is deposited over the gate spacers 90, the second ILD 124, the upper gate electrodes 134U, and the source/drain contacts 144. In some embodiments, the third ILD 154 is a flowable film formed by a flowable CVD method, which is subsequently cured. In some embodiments, the third ILD 154 is formed of a dielectric material such as PSG, BSG, BPSG, USG, or the like, which may be deposited by any suitable method, such as CVD, PECVD, or the like.

In some embodiments, an etch stop layer (ESL) 152 is formed between the third ILD 154 and the gate spacers 90, the second ILD 124, the upper gate electrodes 134U, and the source/drain contacts 144. The ESL 152 may include a dielectric material having a high etching selectivity to the dielectric material of the third ILD 154, such as, silicon nitride, silicon oxide, silicon oxynitride, or the like.

Source/drain vias 158 are formed through the third ILD 154 to electrically couple to the source/drain contacts 144. As an example to form the source/drain vias 158, openings for the source/drain vias 158 are formed through the third ILD 154 and the ESL 152. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 154. The remaining liner and conductive material form the source/drain vias 158 in the openings.

In FIGS. 13A-13B, a planarization process may be performed on the backside of the semiconductor device 120 (e.g., on the substrate 50). In some embodiments, the planarization process may include a combination of CMP and/or etch-back processes, for example. The planarization process and/or etching processes may remove the substrate 50 and the fins 62, exposing the isolation regions 70. Then, one or more etching processes are performed to remove the isolation regions 70. An ILD 162 may be deposited over the backside of the semiconductor device 120, such as over the gate dielectrics 132, the lower gate electrodes 134L, and the lower epitaxial source/drain regions 108L. The ILD 162 is a flowable film formed by a flowable CVD method, which is subsequently cured. In some embodiments, the ILD 162 is formed of a dielectric material such as PSG, BSG, BPSG, USG, or the like, which may be deposited by any suitable method, such as CVD, PECVD, or the like. A removal process may then be performed to level bottom surfaces of the ILD 162 with bottom surfaces of the lower epitaxial source/drain regions 108L. In some embodiments, a planarization process such as a chemical mechanical polish (CMP), an etch-back process, combinations thereof, or the like may be utilized.

After leveling the bottom surfaces of the ILD 162 with the bottom surfaces of the lower epitaxial source/drain regions 108L, portions of the lower epitaxial source/drain regions 108L may be removed using a planarization process that may be performed on the backside of the semiconductor device 120. In some embodiments, the planarization process may comprise for example, a chemical mechanical polish (CMP), an etch-back process, combinations thereof, or the like. After the planarization process is performed, bottom surfaces of the lower epitaxial source/drain regions 108L are exposed within openings (not shown in the Figures) in the ILD 162.

Contact spacers 163 may then be formed on sidewalls of the openings in the ILD 162. The contact spacers 163 may be formed by depositing a dielectric material such as silicon nitride, silicon oxide, silicon oxynitride, or the like, over the ILD 162 and in the openings in the ILD 162 using any suitable deposition process, such as CVD, ALD, or the like. An anisotropic etching process may then be performed to remove portions of the dielectric material, wherein remaining portions of the dielectric material form the contact spacers 163 on the sidewalls of the openings in the ILD 162.

After the formation of the contact spacers 163, source/drain contacts 166 are formed in the openings in the ILD 162 to electrically couple to the lower epitaxial source/drain regions 108L. As an example to form the source/drain contacts 166, a liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the bottom surfaces of the contact spacers 163 and the ILD 162. The remaining liner and conductive material form the source/drain contacts 166 in the openings in the ILD 162. In some embodiments, a planarization process such as a chemical mechanical polish (CMP), an etch-back process, combinations thereof, or the like is utilized. After the planarization process, the bottom surfaces of the contact spacers 163, the ILD 162, and the source/drain contacts 166 are substantially coplanar (within process variations).

Optionally, metal-semiconductor alloy regions 164 are formed at the interfaces between the lower epitaxial source/drain regions 108L and the source/drain contacts 166. The metal-semiconductor alloy regions 164 may be formed using similar processes and materials as those described previously in FIG. 11 for the formation of the metal-semiconductor alloy regions 142.

After the formation of the source/drain contacts 166, an ILD 170 is deposited over the ILD 162, the contact spacers 163, and the source/drain contacts 166. In some embodiments, the ILD 170 is a flowable film formed by a flowable CVD method, which is subsequently cured. In some embodiments, the ILD 170 is formed of a dielectric material such as PSG, BSG, BPSG, USG, or the like, which may be deposited by any suitable method, such as CVD, PECVD, or the like.

In some embodiments, an etch stop layer (ESL) 168 is formed between the ILD 162 and the ILD 170, and between the source/drain contacts 166 and the ILD 170. The ESL 168 may include a dielectric material having a high etching selectivity to the dielectric material of the ILD 170, such as, silicon nitride, silicon oxide, silicon oxynitride, or the like.

Backside gate contacts 174 are formed through the ILD 170 and the ILD 162, and source/drain vias 172 are formed through the ILD 170 to electrically couple to, respectively, the lower gate electrodes 134L and the source/drain contacts 166. As an example to form the backside gate contacts 174 and the source/drain vias 172, first openings for the backside gate contacts 174 are formed through the ILD 162 and the ILD 170, and second openings for the source/drain vias 172 are formed through the ILD 170. The first openings and the second openings may be formed using acceptable photolithography and etching techniques. A liner (not separately illustrated), such as a diffusion barrier layer, an adhesion layer, or the like, and a conductive material are formed in the first openings and the second openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the bottom surface of the ILD 170. The remaining liner and conductive material form the backside gate contacts 174 and the source/drain vias 172 in the first openings and the second openings, respectively. The backside gate contacts 174 and the source/drain vias 172 may be formed in distinct processes, or may be formed in the same process. Although shown as being formed in the same cross-section, it should be appreciated that each of the backside gate contacts 174 and the source/drain vias 172 may be formed in different cross-sections, which may avoid shorting of the contacts. Each backside gate contact 174 may be formed such that it is overlapped by a vertical stack of semiconductor nanostructures 66 (including lower semiconductor nanostructures 66L and upper semiconductor nanostructures 66U), where the semiconductor nanostructures 66 act as channel regions for CFETs.

Advantages can be achieved by forming the backside gate contacts 174 such that each backside gate contact 174 is overlapped by a vertical stack of semiconductor nanostructures 66 (including lower semiconductor nanostructures 66L and upper semiconductor nanostructures 66U), where the semiconductor nanostructures 66 act as channel regions for CFETs. These advantages include reducing a need to provide additional routing space that would be needed if the backside gate contact 174 was not overlapped by the vertical stack of semiconductor nanostructures 66. As a result, the semiconductor nanostructures 66 (e.g., the channel regions of the CFETs) can be designed and fabricated with larger widths W1 that are in the range from 5 nm to 100 nm. The larger widths W1 allow for improved device speed and increased device performance. In addition, the vertical stack of semiconductor nanostructures 66 overlapping the backside gate contact 174 enables increased power delivery through the backside gate contact 174 as a result of the optimized backside gate contact 174 positioning.

The embodiments of the present disclosure have some advantageous features. The embodiments include forming a semiconductor device that includes CFETs. A CFET includes a lower nanostructure-FET and an upper nanostructure-FET. Forming the semiconductor device may comprise forming a fin structure that includes alternating dummy nanostructures and semiconductor nanostructures that are disposed over a fin. The semiconductor nanostructures may subsequently form channel regions for the CFETs. A bottommost dummy nanostructure of the dummy nanostructures may have a thickness that is greater than thicknesses of the other dummy nanostructures. Sidewalls of first ones of the dummy nanostructures (e.g., including the bottommost dummy nanostructure) may be recessed to form sidewall recesses. Spacers may be formed in the sidewall recesses by depositing a dielectric material on sidewalls of the fin structure and in the sidewall recesses of the first ones of the dummy nanostructures using a flowable chemical vapor deposition (FCVD) process. The dielectric material may comprise nitride-based materials such as silicon nitride, or the like. An annealing process may then be performed to cure the dielectric material. After the FCVD process and the annealing process are performed, an etching process (e.g., an anisotropic etching process) may be performed to etch the dielectric material. The remaining portions of the dielectric material in the sidewall recesses form the spacers in the sidewall recesses. After the formation of the spacers, the first ones of the dummy nanostructures may be replaced with gate dielectrics and gate electrodes to form replacement gates, such that a thickness of a first portion of a replacement gate that is disposed between a bottommost surface of the bottommost semiconductor nanostructure and a top surface of the fin is greater than a thickness of a portion of the replacement gates that is disposed between a top surface of each semiconductor nanostructure and a bottom surface of an adjacent semiconductor nanostructure disposed above the semiconductor nanostructure. After the formation of the replacement gates, a backside gate contact may be formed at a location where the backside gate contact is overlapped by the semiconductor nanostructures (e.g., the channel regions of the CFETs), wherein the backside gate contact contacts the first portion of the replacement gate.

One or more embodiments disclosed herein may allow for the greater thickness of the first portion of the replacement gate to minimize threshold voltage (Vₜ) changes of the semiconductor device as a result of possible damage to the first portion of the replacement gate during subsequent etching processes that are used during the formation of the backside gate contact. In addition, the semiconductor nanostructures (e.g., the channel regions of the CFETs) are able to directly overlap the backside gate contact which reduces the need to provide additional routing space that would be needed if the backside gate contact was not overlapped by the semiconductor nanostructures. As a result, the channel regions of the CFETs can be designed and fabricated with larger widths for improved device speed which leads to improved device performance. In addition, the semiconductor nanostructures overlapping the backside gate contact enables increased power delivery through the backside gate contact as a result of the optimized backside gate contact positioning. Further, the use of the FCVD process to form the spacers enables consistent spacer width despite the varying thicknesses between the first portion of the replacement gate and other portions of the replacement gates. The FCVD process, the annealing process, and the etching process may allow the spacers to be formed to provide reliable isolation and prevent shorting between the replacement gates and epitaxial source/drain regions. As a result, device yield and reliability can be improved while maintaining the performance advantages of increased channel widths, enhanced routing capabilities, and optimized threshold voltage control of the semiconductor device.

In accordance with an embodiment, a method includes forming a multi-layer stack over a semiconductor substrate; patterning the multi-layer stack and the semiconductor substrate to form a fin structure, the fin structure including alternating semiconductor nanostructures and dummy nanostructures, where a bottommost dummy nanostructure of the dummy nanostructures has a first thickness, where first dummy nanostructures of the dummy nanostructures are disposed above the bottommost dummy nanostructure, and each of the first dummy nanostructures has a second thickness that is smaller than the first thickness; forming source/drain recesses in the fin structure; etching sidewalls of the first dummy nanostructures and the bottommost dummy nanostructure in the source/drain recesses to form sidewall recesses; forming inner spacers in the sidewall recesses in the first dummy nanostructures and the bottommost dummy nanostructure; and replacing the first dummy nanostructures and the bottommost dummy nanostructure with a gate structure that includes a lower gate structure and an upper gate structure over the lower gate structure. In an embodiment, the method further includes epitaxially growing lower source/drain regions in corresponding ones of the source/drain recesses, where a first channel region defined from a bottommost semiconductor nanostructure of the semiconductor nanostructures extends between the lower source/drain regions; and epitaxially growing upper source/drain regions over the lower source/drain regions in corresponding ones of the source/drain recesses, where a second channel region defined from a first semiconductor nanostructure of the semiconductor nanostructures extends between the upper source/drain regions. In an embodiment, a width of each of the first channel region and the second channel region is in a range from 5 nm to 100 nm. In an embodiment, the method further includes exposing a backside of the lower gate structure; and forming a backside gate contact to electrically connect to the lower gate structure, where the first channel region and the second channel region overlap the backside gate contact. In an embodiment, each of the inner spacers that are formed in the sidewall recesses in the bottommost dummy nanostructure have the first thickness, and each of the inner spacers that are formed in the sidewall recesses in the first dummy nanostructures have the second thickness. In an embodiment, forming the inner spacers in the sidewall recesses in the first dummy nanostructures and the bottommost dummy nanostructure includes depositing a dielectric material in the sidewall recesses in the first dummy nanostructures and the bottommost dummy nanostructure using a flowable chemical vapor deposition (FCVD) process; performing an annealing step to cure the dielectric material; and performing an etching step to etch portions of the dielectric material. In an embodiment, the dielectric material includes silicon nitride. In an embodiment, each inner spacer of the inner spacers that are formed in the sidewall recesses in the bottommost dummy nanostructure has a uniform width in a direction from a top surface of the inner spacer to a bottom surface of the inner spacer.

In accordance with an embodiment, a method includes depositing a multi-layer stack over a semiconductor substrate, the multi-layer stack including alternating channel layers and dummy layers; forming a fin structure from the multi-layer stack and the semiconductor substrate, the fin structure including alternating semiconductor nanostructures and dummy nanostructures, where a bottommost dummy nanostructure of the dummy nanostructures has a first thickness, where first dummy nanostructures of the dummy nanostructures are disposed above the bottommost dummy nanostructure, and each of the first dummy nanostructures has a second thickness that is smaller than the first thickness; forming source/drain recesses in the fin structure; forming inner spacers in sidewall recesses in the first dummy nanostructures and the bottommost dummy nanostructure in the source/drain recesses; forming lower source/drain regions in the source/drain recesses, where lower semiconductor nanostructures of the semiconductor nanostructures extend between the lower source/drain regions; forming upper source/drain regions over the lower source/drain regions, where upper semiconductor nanostructures of the semiconductor nanostructures extend between the upper source/drain regions; replacing the first dummy nanostructures and the bottommost dummy nanostructure with a lower gate stack around the lower semiconductor nanostructures and an upper gate stack around the upper semiconductor nanostructures; and forming a backside gate contact to electrically connect to the lower gate stack, where the lower semiconductor nanostructures and the upper semiconductor nanostructures overlap the backside gate contact. In an embodiment, a width of each of the lower semiconductor nanostructures and the upper semiconductor nanostructures is in a range from 5 nm to 100 nm. In an embodiment, a first portion of the upper gate stack that is disposed above a topmost semiconductor nanostructure of the upper semiconductor nanostructures has a third thickness that is equal to the first thickness. In an embodiment, forming the inner spacers in the sidewall recesses in the first dummy nanostructures and the bottommost dummy nanostructure includes etching sidewalls of the first dummy nanostructures and the bottommost dummy nanostructure in the source/drain recesses to form the sidewall recesses; and performing a flowable chemical vapor deposition (FCVD) process to deposit a dielectric material in the sidewall recesses in the first dummy nanostructures and the bottommost dummy nanostructure. In an embodiment, the dielectric material includes silicon nitride. In an embodiment, each inner spacer of the inner spacers that are formed in the sidewall recesses in the bottommost dummy nanostructure has a uniform width in a direction from a top surface of the inner spacer to a bottom surface of the inner spacer.

In accordance with an embodiment, a semiconductor device includes a plurality of first nanostructures, the plurality of first nanostructures extending between first source/drain regions; a plurality of second nanostructures over the plurality of first nanostructures, the plurality of second nanostructures extending between second source/drain regions; a first gate stack around the plurality of first nanostructures, where a first portion of the first gate stack is disposed below the plurality of first nanostructures; a second gate stack over the first gate stack and disposed around the plurality of second nanostructures, where a first portion of the second gate stack is disposed above the plurality of second nanostructures; gate spacers on sidewalls of the first portion of the second gate stack; and a backside gate contact disposed below and in contact with the first portion of the first gate stack, where the plurality of first nanostructures and the plurality of second nanostructures overlap the backside gate contact. In an embodiment, the first portion of the first gate stack has a first thickness, and a second portion of the first gate stack that is disposed between a first nanostructure of the plurality of first nanostructures and a second nanostructure of the plurality of first nanostructures has a second thickness, where the second nanostructure is adjacent to the first nanostructure, and where the first thickness is greater than the second thickness. In an embodiment, the first portion of the second gate stack has a third thickness that is equal to the first thickness. In an embodiment, the device further includes first inner spacers on sidewalls of the first portion of the first gate stack, where each first inner spacer has the first thickness; and second inner spacers on sidewalls of the second portion of the first gate stack, where each second inner spacer has the second thickness. In an embodiment, the first inner spacers and the second inner spacers include silicon nitride. In an embodiment, each first inner spacer of the first inner spacers has a uniform width in a direction from a top surface of the first inner spacer to a bottom surface of the first inner spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of first nanostructures extending between first source/drain regions;
a plurality of second nanostructures extending between second source/drain regions, wherein the second source/drain regions are disposed over the first source/drain regions;
a first gate stack around the plurality of first nanostructures, wherein a first portion of the first gate stack is disposed below the plurality of first nanostructures, and wherein a second portion of the first gate stack is disposed between adjacent ones of the plurality of first nanostructures;
a second gate stack over the first gate stack and disposed around the plurality of second nanostructures, wherein a first portion of the second gate stack is disposed above the plurality of second nanostructures;
a first inner spacer disposed between a sidewall of the first portion of the first gate stack and a sidewall of a first source/drain region of the first source/drain regions; and
a second inner spacer disposed between a sidewall of the second portion of the first gate stack and the sidewall of the first source/drain region of the first source/drain regions, wherein a thickness of the first inner spacer is different from a thickness of the second inner spacer.

2. The semiconductor device of claim 1, further comprising:
a backside gate contact disposed below and in contact with the first portion of the first gate stack, wherein the plurality of first nanostructures and the plurality of second nanostructures overlap the backside gate contact.

3. The semiconductor device of claim 1, wherein the first inner spacer and the second inner spacer comprise silicon nitride.

4. The semiconductor device of claim 1, wherein the thickness of the first inner spacer is greater than the thickness of the second inner spacer.

5. The semiconductor device of claim 4, wherein a second portion of the second gate stack is disposed between adjacent ones of the plurality of second nanostructures, wherein a third inner spacer is disposed between a sidewall of the second portion of the second gate stack and a sidewall of a first source/drain region of the second source/drain regions, wherein a thickness of the third inner spacer is different from a thickness of the first inner spacer.

6. The semiconductor device of claim 5, wherein the thickness of the first inner spacer is greater than the thickness of the third inner spacer.

7. The semiconductor device of claim 6, wherein the thickness of the second inner spacer is equal to the thickness of the third inner spacer.

8. A semiconductor device comprising:
a plurality of first nanostructures extending between first source/drain regions;
a plurality of second nanostructures extending between second source/drain regions, wherein the second source/drain regions are disposed over the first source/drain regions;
an isolation structure disposed between the plurality of first nanostructures and the plurality of second nanostructures, wherein the isolation structure has a first thickness; and
a first gate stack around the plurality of first nanostructures, wherein a first portion of the first gate stack is disposed below the plurality of first nanostructures, and wherein a second portion of the first gate stack is disposed between adjacent ones of the plurality of first nanostructures, wherein the first portion of the first gate stack has a second thickness, wherein the second portion of the first gate stack has a third thickness, and wherein the second thickness is greater than the first thickness and the third thickness.

9. The semiconductor device of claim 8, wherein the isolation structure comprises silicon nitride.

10. The semiconductor device of claim 8, wherein the first thickness of the isolation structure is greater than the third thickness of the second portion of the first gate stack.

11. The semiconductor device of claim 8, further comprising:
a second gate stack over the first gate stack and disposed around the plurality of second nanostructures, wherein a first portion of the second gate stack is disposed above the plurality of second nanostructures, and wherein a second portion of the second gate stack is disposed between adjacent ones of the plurality of second nanostructures.

12. The semiconductor device of claim 11, wherein the second portion of the second gate stack has a fourth thickness, and wherein the second thickness of the first portion of the first gate stack is different from the fourth thickness of the second portion of the second gate stack.

13. The semiconductor device of claim 12, wherein the second thickness of the first portion of the first gate stack is greater than the fourth thickness of the second portion of the second gate stack.

14. A method comprising:
forming a fin structure comprising alternating semiconductor nanostructures and dummy nanostructures, wherein a bottommost dummy nanostructure of the dummy nanostructures has a first thickness, wherein first dummy nanostructures of the dummy nanostructures are disposed above the bottommost dummy nanostructure, and each of the first dummy nanostructures has a second thickness that is smaller than the first thickness;
forming source/drain recesses in the fin structure;
forming first inner spacers in sidewall recesses in the first dummy nanostructures in the source/drain recesses, wherein the first inner spacers have a thickness that is equal to the second thickness;
forming second inner spacers in sidewall recesses in the bottommost dummy nanostructure in the source/drain recesses, wherein the second inner spacers have a thickness that is equal to the first thickness; and
replacing the first dummy nanostructures and the bottommost dummy nanostructure with a gate structure that comprises a lower gate structure and an upper gate structure over the lower gate structure.

15. The method of claim 14, further comprising:
forming lower source/drain regions in the source/drain recesses, wherein lower semiconductor nanostructures of the semiconductor nanostructures extend between the lower source/drain regions; and
forming upper source/drain regions over the lower source/drain regions, wherein upper semiconductor nanostructures of the semiconductor nanostructures extend between the upper source/drain regions.

16. The method of claim 15, wherein replacing the first dummy nanostructures and the bottommost dummy nanostructure with the gate structure comprises forming the lower gate structure around the lower semiconductor nanostructures and the upper gate structure around the upper semiconductor nanostructures.

17. The method of claim 16, further comprising:
forming a backside gate contact to electrically connect to the lower gate structure, wherein the lower semiconductor nanostructures and the upper semiconductor nanostructures overlap the backside gate contact.

18. The method of claim 16, wherein a width of each of the lower semiconductor nanostructures and the upper semiconductor nanostructures is in a range from 5 nm to 100 nm.

19. The method of claim 16, wherein the first inner spacers and the second inner spacers comprise silicon nitride.

20. The method of claim 14, wherein the second inner spacers have a thickness that is in a range from 2 nm to 30 nm.
